(19) United States
(12) Patent Application Publication
(10) Pub. No.: US 2018/0128869 A1
(43) Pub. Date: May 10, 2018

(54) FAILURE LOCATION SPECIFYING DEVICE AND FAILURE LOCATION SPECIFYING METHOD

(71) Applicant: Renesas Electronics Corporation, Tokyo (JP)

(72) Inventor: Junpei Nonaka, Ibaraki (JP)

(21) Appl. No.: 15/715,524

(22) Filed: Sep. 26, 2017

(30) Foreign Application Priority Data
Nov. 4, 2016 (JP) 2016-216184

(51) Int. Cl. G01R 31/26; G01R 31/308; G01R 23/17

(52) U.S. Cl. CPC G01R 31/2621; G01R 23/17; G01R 31/308

(57) ABSTRACT

A failure location specifying device that can specify a failure location even if the spatial resolution is insufficient includes: an EOFM measurement unit that calculates a phase difference between a measurement signal on the basis of reflected light in accordance with the operation of a circuit element arranged in a semiconductor device and a reference signal, and generates a phase map of the circuit element in the semiconductor device. A circuit simulation unit calculates the operation waveform of a circuit element included in the field of view that is extracted by a circuit extraction unit by a simulation. A phase calculation unit calculates a phase on the basis of the operation waveform calculated by the circuit simulation unit; and a phase map generation unit generates a phase map of the circuit element on the basis of the phase calculated by the phase calculation unit.

### CROSS-REFERENCE TO RELATED APPLICATIONS

The disclosure of Japanese Patent Application No. 2016-216184 filed on Nov. 4, 2016 including the specification, drawings and abstract is incorporated herein by reference in its entirety.

### BACKGROUND

The present invention relates to a failure location specifying device and a failure location specifying method, and particularly to a failure location specifying device and a failure location specifying method for specifying a failure location in a semiconductor device using a laser beam.

As a technique for specifying a failure location of a semiconductor device, for example, there is a technique of a light emission analysis in which a semiconductor device operated by a test pattern is irradiated with a laser beam and analyzed using reflected light from the semiconductor device. As the techniques of the light emission analysis, for example, LVP (Laser Voltage Probing), LVI (Laser Voltage Imaging), EOP (Electro Optical Probing), EOFM (Electro Optical Frequency Mapping), an emission microscope, and the like are known.

For example, an analyzer using LVI is described in Japanese Unexamined Patent Application Publication No. 2007-64975. Further, an analyzer using EOFM is described in “Introduction of new function, EO probing unit/new IR-OBIRCH amplifier, The 33rd Nano Testing Symposium Proceedings, P. 95 to P. 98, Nov. 13, 2013” and “Rear-surface timing analysis of 40 nm process product by Electro Optival Probing/Electro Optical Frequency Mapping, The 34th Nano Testing Symposium Proceedings, P. 223 to P. 228, Nov. 12, 2014”. Furthermore, “Realization of random logic operation analysis by short-cycle test pattern, The 35th Nano Testing Symposium Proceedings, P. 203 to P. 208, Nov. 11, 2015” describes that a short-cycle test pattern is used in an analyzer using EOFM.

### SUMMARY

An outline of the analyzer using LVI will be described below by using FIG. 2 of Japanese Unexamined Patent Application Publication No. 2007-64975. It should be noted that reference numerals in parentheses are the same as those in FIG. 2 of Japanese Unexamined Patent Application Publication No. 2007-64975 in the description. A laser beam (204) is irradiated onto a semiconductor device (260) when a test pattern (242) is repeatedly (in a loop manner) applied to the semiconductor device (260) and the semiconductor device (260) is operated in a loop manner in accordance with the test pattern. Reflected light from the semiconductor device (260) is detected by a photodetector (236). In the detected signal from the photodetector (236), the amplitude (refer to 244) of a frequency component corresponding to the repeated cycle (loop cycle) of the test pattern is obtained. A two-dimensional amplitude map on the basis of the detected amplitude is displayed by repeating the above-described detection while changing the irradiation position of the laser beam.

The intensity of the reflected light at the position irradiated with the laser beam is changed by on/off of a transistor (circuit element) arranged at the irradiation position by the action of the photoelectric effect. Accordingly, it is possible to specify the position of the transistor operated at the same cycle as the test pattern by referring to the displayed two-dimensional amplitude map. Further, the shape of the two-dimensional amplitude map to be displayed differs depending on a case where a failure does not occur and a case where a failure occurs. Therefore, it is possible to specify a failure location by specifying a difference with the two-dimensional amplitude map in the case where a failure does not occur.

On the other hand, the analyzer using EOFM can measure a two-dimensional phase map in addition to the two-dimensional amplitude map of the semiconductor device as described above. Even in the EOFM analyzer, a test pattern is supplied to a semiconductor device in a loop manner, and a transistor arranged in the semiconductor device is operated in accordance with the loop cycle of the test pattern. At this time, a laser beam is irradiated. In the case of EOFM, reflected light is mainly measured as a change in a potential difference between the drain and the source of the transistor. For the transistor operated at a designated frequency (for example, the loop frequency of the test pattern), a phase difference between a change (corresponding to a change in the potential difference between the drain and the source) in the reflected light and the waveform of a reference trigger signal (reference signal) serving as a reference is obtained to be represented as a two-dimensional phase map according to the semiconductor device. Namely, the two-dimensional phase map two-dimensionally displays a phase difference between the timing of the operation of the transistor arranged in the semiconductor device and operated at the designated frequency and the waveform of the reference trigger signal. In this case, the phase difference is represented by colors, and the phase map is displayed in color. Namely, a discrete phase difference corresponds to a pure color, and the location where the transistor is arranged is colored with a pure color corresponding to the phase difference of the transistor to be displayed in color.

An example of specifying a failure location using the EOFM analyzer will be described below. Here, a transistor (circuit element) arranged at a specific position of a semiconductor device will be described as an example. In the case where the operation timing of the circuit element is delayed (defective product), the phase difference with the reference trigger signal differs as compared to the case where the circuit element located at a specific position is operated at correct operation timing in accordance with the test pattern (non-defective product). Therefore, when comparing the phase maps of the non-defective product and the defective product with each other, the circuit elements at specific positions are displayed in different colors on both maps. Accordingly, the position of the circuit element with a failure in the semiconductor device can be specified.

In the EOFM analyzer, if the spatial resolution thereof is insufficient as compared to the size of the circuit element (the size of the transistor), it is difficult to associate the phase map with the circuit elements arranged in the semiconductor device, and it is impossible to specify a failure location in the semiconductor device from the phase map. For example, the circuit elements arranged close to each other in the semiconductor device are represented by a color corresponding to one phase difference in the phase map, and it is impossible to specify a failure location.

None of Japanese Unexamined Patent Application Publication No. 2007-64975, “Introduction of new function, EO probing unit/new IR-OBIRCH amplifier, The 33rd Nano Testing Symposium Proceedings, P. 95 to P. 98, Nov. 13, 2013”, “Rear-surface timing analysis of 40 nm process product by Electro Optival Probing/Electro Optical Frequency Mapping, The 34th Nano Testing Symposium Proceedings, P. 223 to P. 228, Nov. 12, 2014”, and “Realization of random logic operation analysis by short-cycle test pattern, The 35th Nano Testing Symposium Proceedings, P. 203 to P. 208, Nov. 11, 2015” describes a problem in the case where the spatial resolution is insufficient in the EOFM analyzer.

The other objects and novel features will become apparent from the description of the specification and the accompanying drawings.

A failure location specifying device according to one embodiment includes a measurement unit, a circuit extraction unit, a simulation unit, a phase calculation unit, and a phase map generation unit. Here, the measurement unit calculates a phase difference between a measurement signal on the basis of reflected light in accordance with the operation of a circuit element arranged in a semiconductor device and a reference signal, and generates a phase map of the circuit element in the semiconductor device. The circuit extraction unit extracts the circuit element included in the field of view in the semiconductor device, and the simulation unit calculates the operation waveform of the circuit element extracted by the circuit extraction unit by a simulation. Further, the phase calculation unit calculates a phase on the basis of the operation waveform calculated by the simulation unit, and the phase map generation unit generates a phase map of the extracted circuit element on the basis of the phase calculated by the phase calculation unit. The phase map generated by the measurement unit and the phase map generated by the phase map generation unit are used to specify a failure location. For example, the failure location is specified by collating both phase maps with each other.

According to one embodiment, it is possible to provide a failure location specifying device that can specify a failure location even if the spatial resolution is insufficient.

### BRIEF DESCRIPTION OF THE DRAWINGS

FIG. 1 is a block diagram for showing a configuration of a failure location specifying device according to a first embodiment;

FIG. 2 is a block diagram for showing details of the failure location specifying device according to the first embodiment;

FIG. 3 is a diagram for explaining generation of a phase map according to the first embodiment;

FIG. 4 is a diagram for explaining generation of the phase map according to the first embodiment;

FIGS. 5A and 5B are diagrams each explaining generation of the phase map according to the first embodiment;

FIG. 6 is a block diagram for showing details of a failure location specifying device according to a second embodiment;

FIGS. 7A to 7C are diagrams each explaining an operation of a phase map transformation unit according to the second embodiment;

FIGS. 8A and 8B are diagrams each showing the phase map of a non-defective semiconductor device;

FIGS. 9A and 9B are diagrams each showing the phase map of a defective semiconductor device;

FIGS. 10A and 10B are diagrams each showing the phase map generated on the basis of a circuit simulation according to the second embodiment;

FIG. 11 is a block diagram for showing a configuration of a circuit simulation unit according to a third embodiment;

FIG. 12 is a plan view for explaining a failure location specifying device according to a modified example of the third embodiment;

FIG. 13 is a plan view for showing a predetermined region in a semiconductor device; and

FIGS. 14A and 14B are diagrams each showing a phase map generated by using an EOFM analyzer.

### DETAILED DESCRIPTION

Hereinafter, embodiments of the present invention will be described in detail on the basis of the drawings. It should be noted that the same parts are followed by the same signs in principle in all the drawings for explaining the embodiments, and the explanation thereof will not be repeated in principle. Hereinafter, a failure location specifying device using EOFM will be described as an example, but the present invention is not limited thereto. The present invention can be applied to a failure location specifying device and a failure location specifying method to form a phase map by obtaining a phase difference between a reference signal and a measurement signal of a designated frequency among measurement signals on the basis of reflected light.

### First Embodiment

In order to easily understand a first embodiment, a case in which the spatial resolution of an analyzer is insufficient as compared to the size of a circuit element (transistor) will be described first. Hereinafter, a case in which a field effect transistor (hereinafter, also referred to as an FET) is used as a transistor will be described as an example, but the present invention is not limited thereto.

### Insufficient Spatial Resolution

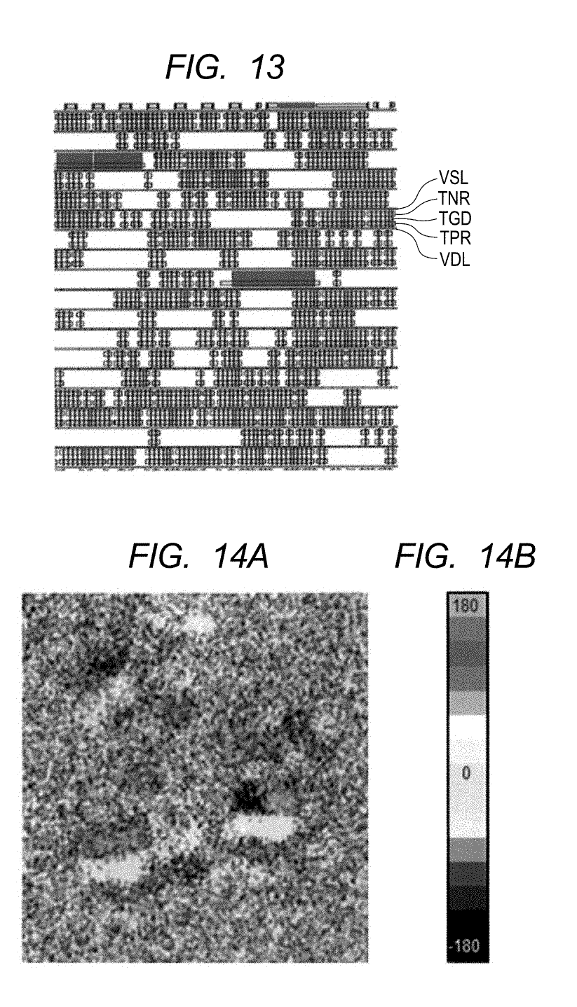

FIG. 13 is a plan view for showing a predetermined region in a semiconductor device. Here, it is assumed that the predetermined region is the observation field of view of the EOFM analyzer. A plurality of FETs and a plurality of voltage lines are arranged in the region (within the observation field of view) shown in FIG. 13. Here, the FETs are configured using P-channel-type FETs (hereinafter, also referred to as P-type FETs) and N-channel-type FETs (hereinafter, also referred to as N-type FETs). The P-type FET includes a drain region and a source region formed by a P-type semiconductor region and a gate electrode arranged between the drain region and the source region. As similar to the above, the N-type FET includes a drain region and a source region formed by an N-type semiconductor region and a gate electrode arranged between the drain region and the source region.

In FIG. 13, in order to avoid making the drawing complicated, signs are given to only the configurations of one P-type FET and one N-type FET. Namely, TPR denotes a drain region and a source region configuring the P-type FET, and TNR denotes a drain region and a source region configuring the N-type FET in FIG. 13. Further, TGD denotes a common gate electrode arranged in the P-type FET and the N-type FET. In FIG. 13, VSL denotes a voltage line (ground line) for supplying a ground voltage Vs, and VDL denotes a voltage line (power source line) for supplying a power source voltage Vd. The P-type FET and the N-type FET are arranged between the voltage lines VSL and VDL, and source-drain paths are coupled in series between the voltage lines VSL and VDL. The other P-type FETs and N-type FETs similarly have drain regions and source regions arranged between the voltage lines VSL and VDL.

Although not shown in FIG. 13, the gate electrodes of the P-type and N-type FETs are coupled to the drain regions of the other P-type and N-type FETs. Accordingly, when a test pattern is supplied, the P-type and N-type FETs are sequentially operated in accordance with the test pattern. When one of the FETs is turned on in accordance with the test pattern, a potential difference is generated between the source region and the drain region configuring the FET. When a laser beam is irradiated, the reflected light changes in accordance with the potential difference between the source region and the drain region.

FIGS. 14A and 14B show a phase map generated by analyzing the inside of the observation field of view shown in FIG. 13 by using the EOFM analyzer. The phase map is a map in which a phase difference between a reference signal and a measurement signal of a designated frequency among measurement signals on the basis of reflected light is indicated using a color. In FIG. 14A, colors corresponding to the phase differences are indicated by black shades. FIG. 14B is a scale for showing correspondences between the shades shown in FIG. 14A and the phase differences. 360 degrees from the in-phase (0) with the reference signal up to 180 degrees (180) in the direction advanced with respect to the reference signal and up to 180 degrees (−180) in the direction delayed with respect to the reference signal are discretely separated into 15 colors (indicated by shades).

In FIG. 14A, an FET operated with a phase difference corresponding to the shade (color) shown in FIG. 14B is arranged in a region having the same shade (color) as the shade (color) shown in FIG. 14B. On the other hand, in FIG. 14A, regions having no shades same as those shown in FIG. 14B exist in a noise state. Namely, regions having color depths different from the shades shown in FIG. 14B exist. In FIGS. 14A and 14B, the phase differences are shown by the shades by being discretely separated into 15. In the following description, a case in which the phase differences are shown by colors will be described. In the case where the phase differences are shown by colors, the phase differences of 360 degrees are shown by being discretely separated into 15 pure colors (blue, orange, and the like). In such a case, in FIG. 14A, there are regions colored with pure colors and regions colored with colors mixed with various pure colors (hereinafter, also referred to as mixed colors or intermediate colors) instead of the pure colors. In a region colored with a pure color, an FET operated with a phase difference corresponding to the pure color is arranged. On the other hand, noise-like signals having various phase differences exist in regions colored with the mixed colors. In the regions colored with the mixed colors, non-operated FETs are arranged, or the regions colored with the mixed colors are empty regions where no FETs are arranged.

It should be noted that a region with an FET arranged and colored with the shade (pure color) corresponding to the phase difference of the FET in the phase map is also referred to as an EOFM reaction region in some cases in the specification because the reaction of EOFM (EOFM reaction) occurs.

The spatial resolution of the analyzer is insufficient as compared to the sizes of the drain region, the source region, and the gate electrode of one FET. Therefore, when FIG. 13 is compared with FIG. 14B, the size of the EOFM reaction region is larger and spreads as compared to the size of one FET. Namely, the size of the EOFM reaction region is detected larger than the size of one FET. Further, the shape of the EOFM reaction region does not reflect the shapes of the drain region, the source region, and the gate electrode of the FET arranged in the semiconductor device. Therefore, even if only the EOFM reaction region is observed in FIG. 14 and compared with FIG. 13, it is extremely difficult to specify the FET where the EOFM reaction occurs in the semiconductor device.

In the case where a failure location is specified using an analyzer, for example, it is conceivable that a phase map is obtained from each of non-defective and defective products and a failure location is estimated from a difference between the obtained phase maps. In this case, in order to investigate the cause of a defective product, for example, it is conceivable that a cross section of the semiconductor device is obtained for a region including the estimated failure location, and the cross section is observed. However, it is difficult to specify the position of the FET arranged in the semiconductor device from the EOFM reaction region in the phase map. Thus, it is difficult to specify the position of the semiconductor device whose cross section is obtained, and it is impossible to investigate the cause by observing the cross section.

### Failure Location Specifying Device

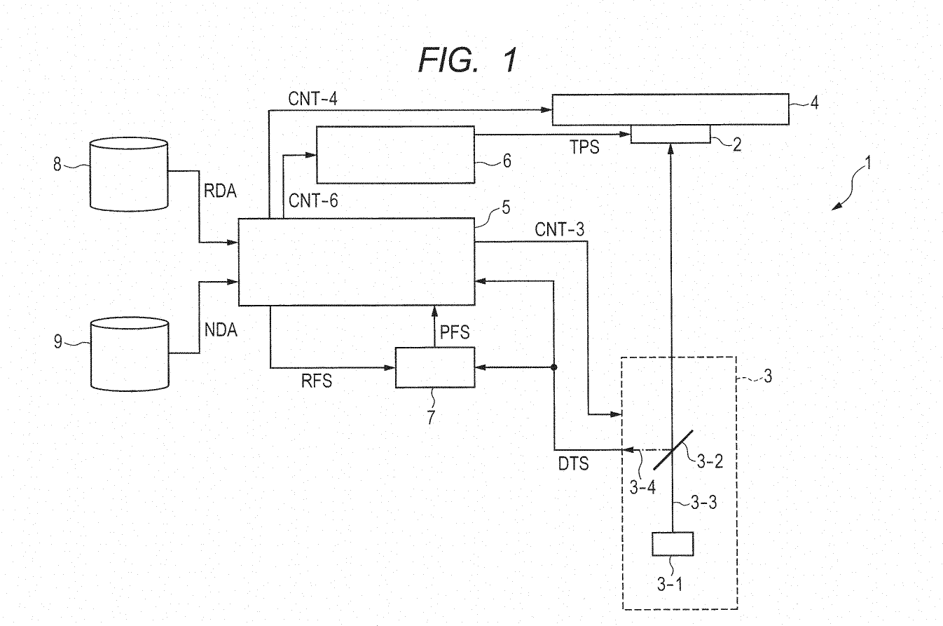

FIG. 1 is a block diagram for showing a configuration of a failure location specifying device according to a first embodiment. In the drawing, the reference numeral 1 denotes a failure location specifying device. The failure location specifying device 1 is not particularly limited, but includes a laser beam detector 3, a stage 4, a computer 5, a test pattern generator 6, a spectrum analyzer 7, and storage units 8 and 9. Further, in the drawing, the reference numeral 2 denotes a semiconductor device in which a failure location is specified by the failure location specifying device 1.

In the semiconductor device 2, the P-type FETs and the N-type FETs are arranged as shown in FIG. 13. The semiconductor device 2 is mounted on the stage 4. The stage 4 is moved in accordance with a control signal (stage movement control signal) CNT-4 from the computer 5. In the first embodiment, for example, the stage 4 is moved to the left and right in FIG. 1 in accordance with the control signal CNT-4. Since the semiconductor device 2 is mounted on the stage 4, the semiconductor device 2 can be also moved to the left and right as the stage 4 is moved.

The laser beam detector 3 includes a laser beam generating unit 3-1 for generating a laser beam and a movable mirror 3-2. The laser beam generating unit 3-1 generates a laser beam 3-3 in an operation (failure location specifying operation) of specifying a failure location. The generated laser beam 3-3 passes through the movable mirror 3-2 to be irradiated onto the semiconductor device 2. The laser beam 3-3 is reflected by the semiconductor device 2, and the reflected laser beam (reflected light) is reflected by the movable mirror 3-2 to be a reflected laser beam 3-4. The reflected laser beam 3-4 is converted into a measurement signal DTS on the basis of the reflected laser beam 3-4 by a converter (not shown), and is supplied to the spectrum analyzer 7 and the computer 5.

The movable mirror 3-2 changes the angle at which the laser beam is reflected in accordance with a control signal (mirror movable control signal) CNT-3 from the computer 5 in the failure location specifying operation. Accordingly, the laser beam from a predetermined range in the semiconductor device 2 can be supplied to the converter as the reflected laser beam 3-4 without moving the stage 4 by changing the angle of the movable mirror 3-2 by the control signal CNT-3. Although not particularly limited, the predetermined range in which the laser beam can be supplied to the converter as the reflected laser beam 3-4 by changing the angle of the movable mirror 3-2 is the observation field of view of the failure location specifying device 1. In the failure location specifying operation, after observing in the particular observation field of view, another region is observed as the observation field of view by moving the stage 4.

The spectrum analyzer 7 performs frequency-resolving for the measurement signal DTS, calculates a phase difference between the waveforms of the reference trigger signal RFS and the measurement signal of the designated frequency among the resolved frequencies, and supplies the calculated phase difference PFS to the computer 5. The failure location specifying device 1 may not have the spectrum analyzer 7. For example, the computer 5 may calculate the phase difference PFS on the basis of the waveforms of the measurement signal DTS and the reference trigger signal. As an example, the computer 5 may perform a fast Fourier transform operation for the measurement signal DTS to calculate the phase difference PFS on the basis of the data of the designated frequency obtained by the operation and the data of the reference trigger signal RFS.

The test pattern generator 6 is controlled by a control signal (test control signal) CNT-6 from the computer 5, and periodically supplies a test pattern TPS to the semiconductor device 2 in the failure location specifying operation. In the first embodiment, the test pattern TPS is a predetermined time-series signal pattern, and the predetermined time-series signal pattern is periodically and repeatedly supplied to the semiconductor device 2. Accordingly, the semiconductor device 2 periodically and repeatedly executes the same operation in the failure location specifying operation.

The storage unit 9 stores data of a net list that defines connection among circuit elements such as the FETs arranged in the semiconductor device 2, namely, circuit connection data NDA. Further, the storage unit 8 stores layout data RDA that defines the arrangement of the circuit elements arranged in the semiconductor device 2.

In the first embodiment, although not particularly limited, the layout data RDA includes correspondence information indicating a correspondence relationship between the circuit element designated by the circuit connection data NDA and the circuit element to be arranged. Namely, a correspondence relationship between the circuit element and the position of the circuit element in the semiconductor device can be grasped by referring to the layout data RDA.

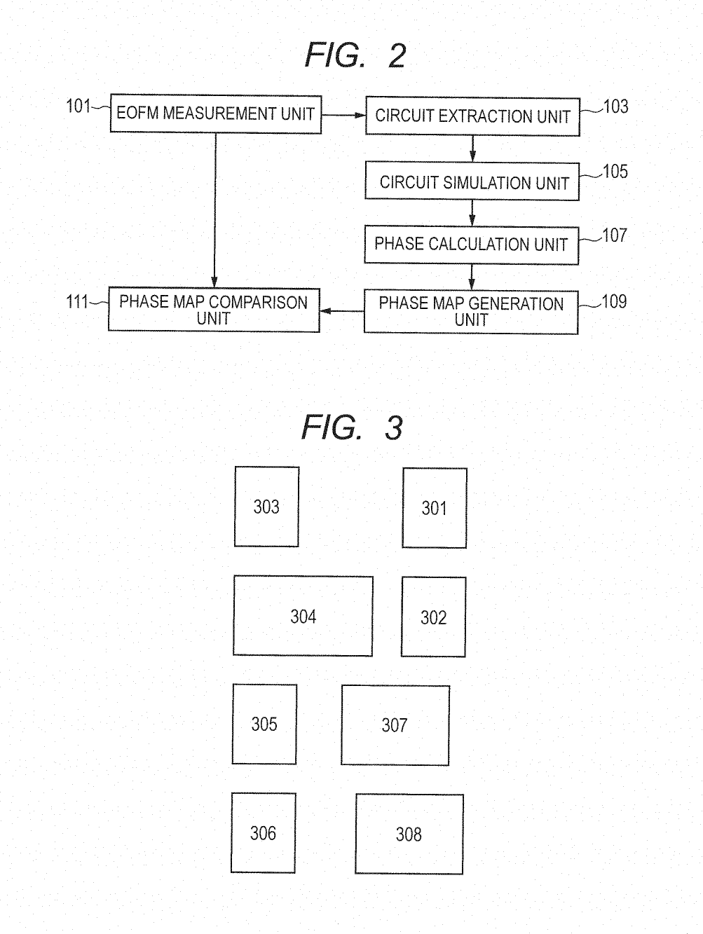

Next, as will be described in detail using FIG. 2, the computer 5 generates a phase map of circuit elements using the EOFM technique in the failure location specifying operation. Further, the computer 5 conducts a circuit simulation on the basis of the layout data RDA, the circuit connection data NDA, and the like to generate another phase map of circuit elements. The computer 5 superimposes the two kinds of generated phase maps to be displayed on, for example, a display device (not shown), so that a user (operator) can specify the failure location.

### Failure Location Specifying Operation

FIG. 2 is a block diagram for showing details of the failure location specifying device according to the first embodiment. Although not particularly limited, each of blocks 101, 103, 105, 107, and 109 shown in FIG. 2 is realized by the computer 5 executing a program corresponding to each block.

In FIG. 2, the reference numeral 101 denotes a measurement unit (EOFM measurement unit) using the EOFM technique, 103 denotes a circuit extraction unit, 105 denotes a circuit simulation unit, 107 denotes a phase calculation unit, 109 denotes a phase map generation unit, and 111 denotes a phase map comparison unit. The failure location specifying operation will be described using FIG. 1 and FIG. 2.

The EOFM measurement unit 101 is provided with a CAD navigation function. When the coordinate range (position range) of the observation target is designated on the layout of the semiconductor device 2, the stage 4 is moved by the control signal CNT-4 (FIG. 1), and the semiconductor device 2 is moved so that a laser beam 3-1 is irradiated onto the coordinate range of the observation target by the CAD navigation function. After the stage 4 is moved, the phase difference PFS is obtained by the spectrum analyzer 7 while changing the angle of the movable mirror 3-2 by the control signal CNT-3 (FIG. 1). Namely, the measurement signals DTS in the observation field of view are frequency-resolved by the spectrum analyzer 7, the measurement signal of the designated frequency among the measurement signals DTS is extracted, and the phase difference PFS between the measurement signal DTS and the reference trigger signal RFS is calculated. The calculated phase difference PFS is supplied to the computer 5. The EOFM measurement unit 3 generates a phase map in the observation field of view on the layout diagram on the basis of the supplied phase difference PFS. In this case, a phase map colored corresponding to the phase difference is generated.

Further, the EOFM measurement unit 101 obtains coordinate range information of the circuit element from the coordinate range of the observation target designated on the layout of the semiconductor device 2, and supplies the obtained coordinate range information of the circuit element to the circuit extraction unit 103. The circuit extraction unit 103 specifies and extracts the circuit element included in the designated coordinate range from the supplied coordinate range information of the circuit element. In the extraction, the circuit extraction unit 103 uses the layout data RDA stored in the storage unit 8. Namely, the circuit element arranged in the designated coordinate range is specified from the supplied coordinate range information of the circuit element. The circuit element in the circuit connection data NDA corresponding to the specified circuit element is specified using the correspondence information included in the layout data RDA. To put is briefly, the circuit element on the circuit connection data NDA corresponding to the circuit element arranged in the coordinate range of the observation target in the semiconductor device 2 is specified.

Next, in the circuit simulation unit 105, the circuit simulation of the semiconductor device 2 when the test pattern TPS is supplied to the semiconductor device 2 is conducted using the circuit connection data NDA stored in the storage unit 9. Further, when conducting the circuit simulation, the circuit simulation unit 105 obtains the operation waveform of the circuit element extracted by the circuit extraction unit 103. The circuit simulation unit 105 may simulate the entire operation of the semiconductor device 2 with respect to the test pattern TPS to obtain the operation waveform of only the circuit element extracted by the circuit extraction unit 103, or may execute the circuit simulation only for the circuit element extracted by the circuit extraction unit 103 to obtain the operation waveform.

The phase calculation unit 107 calculates a phase difference between the operation waveform obtained by the circuit simulation unit 105 and the waveform of the reference trigger signal RFS. An example of the calculation of the phase difference will be described later using the drawing, and thus the detailed explanation thereof is omitted here.

The phase map generation unit 109 colors the circuit element in the view region on the layout diagram corresponding to the semiconductor device 2 with a color corresponding to the phase difference calculated by the phase calculation unit 107. The circuit extraction unit 103 has already obtained a correspondence between the position of the circuit element on the layout and the circuit element on the circuit connection. Therefore, it is possible to color the circuit element on the layout with an appropriate color by diverting the correspondence relationship.

The phase map comparison unit 111 compares the phase map generated by the EOFM measurement unit 101 with the phase map generated by the phase map generation unit 109. Namely, the phase map comparison unit 111 compares the phase map on the basis of the EOFM reaction measured by the EOFM technique with the phase map generated on the basis of the circuit simulation. Accordingly, the EOFM reaction region measured by the EOFM technique and the circuit element on the layout can correspond to each other.

In the above description, an example in which the phase map on the basis of the EOFM reaction is generated first by the EOFM measurement unit 101 has been described. However, the phase map may be generated by the EOFM measurement unit 101 after the phase map generation unit 109.

### Example of Generating Phase Map

Next, operations of the circuit extraction unit 103, the circuit simulation unit 105, the phase calculation unit 107, and the phase map generation unit 109 will be described using an example. FIG. 3 to FIG. 5 are diagrams each explaining generation of the phase map according to the first embodiment.

FIG. 3 is a plan view for showing a region of a part of the semiconductor device 2, and the positions of circuit elements 301 to 308 arranged in the view region are schematically illustrated. In FIG. 3, the circuit elements 301, 303, 306, and 308 denote P-type FETs, and the circuit elements 302, 304, 305, and 307 denote N-type FETs. The FETs have gate electrodes, drain regions, and source regions. However, in order to simplify the explanation, the gate electrodes are omitted, and the drain region and the source region are collectively illustrated as one block. For example, in FIG. 3, the block 301 shows the drain region and the source region of the FET 301, and the gate electrode is omitted. The same applies to the other FETs. Further, lines coupling the FETs 301 to 308 to each other are omitted.

When a test pattern is supplied to the FETs and the FETs are turned on, a current flows between the drain region and the source region, and a potential difference is generated between the drain region and the source region. When a laser beam is irradiated, reflected light is changed mainly in accordance with a change in the potential difference between the drain and the source. Therefore, in the case where a laser beam is irradiated into the view region shown in FIG. 3, the potential difference (the potential difference between the drain region and the source region) is generated in the blocks 301 to 308 in accordance with ON/OFF operations of the FETs 301 to 308, and the reflected light from each block is changed. It should be noted that although schematically shown, the blocks 301 to 308 shown in FIG. 3 illustrate the planar shapes of the diffusion regions (regions where the drain regions and the source regions are combined) of the FETs 301 to 308.

When the EOFM measurement unit 101 generates a colored phase map, a phase difference between the reference trigger signal RFS and the measurement signal (measurement of the designated frequency) on the basis of the reflected light from the blocks 301 to 308 is obtained, and each block is colored with a color corresponding to the obtained phase difference to generate the phase map of the circuit.

The circuit extraction unit 103 specifies and extracts the FETs 301 to 308 in the circuit connection data NDA on the basis of the coordinate range information of the circuit element from the EOFM measurement unit 101 using the correspondence information in the layout data RDA. Accordingly, the positions of the blocks 301 to 308 and the FETs 301 to 308 as the circuit elements are associated with each other on a one-to-one basis.

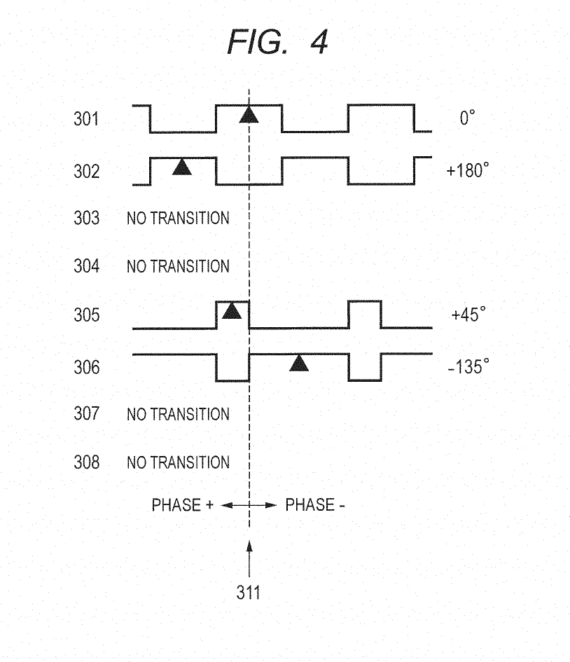

FIG. 4 is a waveform diagram for showing operation waveforms of the FETs 301 to 308. The circuit simulation unit 105 conducts the circuit simulation on the basis of the circuit connection data NDA, and the extracted operation waveforms of the FETs 301 to 308 are shown in FIG. 4. In FIG. 4, the horizontal axis represents time and the vertical axis represents the voltage of each operation waveform. In the drawing, the reference numerals 301 to 308 denote the operation waveforms each showing a change in the potential difference between the drain region and the source region of each of the FETs 301 to 308. In FIG. 4, the ON state or the OFF state are continued in the FETs 303, 304, 307, and 308 according to the test pattern, and the potential difference does not transit. Therefore, the operation waveforms 303, 304, 307, and 308 are omitted in FIG. 4. On the other hand, the ON state and the OFF state are complementarily repeated in the FETs 301 and 302 according to the test pattern, and the ON state and the OFF state are complementarily repeated also in the FETs 305 and 306 according to the test pattern. Accordingly, the potential difference between the drain region and the source region of each of the FETs 301, 302, 305, and 306 is changed (transited).

The change in the potential difference between the drain region and the source region of each of the FETs 301 to 308 shown in FIG. 4 is supplied to the phase calculation unit 107 as an operation waveform. The phase calculation unit 107 calculates a phase difference between the supplied operation waveform and the reference trigger signal RFS. Various configurations of calculating the phase difference of the operation waveform are conceivable. For example, the operation waveform is subjected to Fourier transform, and only the phase of the operation waveform of the designated frequency component is extracted. Alternatively, by regarding the operation waveform as the waveform of a binary logic signal, the time difference between the timing at the center of a period during which the logic waveform becomes the high level and the timing at which the waveform of the reference trigger signal RFS is changed may be obtained as a phase difference. FIG. 4 shows an example of calculating the phase difference using the latter configuration.

In FIG. 4, the reference numeral 311 denotes the timing (reference timing) at which the waveform of the reference trigger signal RFS is changed. In addition, the symbol ▴ denotes the timing at the center of a period during which the logic waveform (operation waveform) becomes the high level. For example, the symbol ▴ attached to the logic waveform (operation waveform) 301 denotes the timing at the center of a period during which the logic waveform 301 becomes the high level.

Although not particularly limited, it is assumed in the first embodiment that the phase is advanced (phase +) in the case where the timing of the symbol ▴ is located before the reference timing 311 in terms of time, and the phase is delayed (phase −) in the case where the timing of the symbol ▴ is located after the reference timing 311 in terms of time. In the drawing, the timing of the symbol ▴ of the logic waveform 301 is overlapped with the reference timing 311, and thus the phase difference with the reference signal RFS is 0 degree (0°). On the other hand, the timing of the symbol ▴ of the logic waveform (operation waveform) 302 is located before the reference timing 311, and the phase difference is +180 degrees (+180°) in the example of FIG. 4. Further, the phase difference of the logic waveform (operation waveform) 305 is +45 degrees (+45°), and the phase difference of the operation waveform 306 is −135 degrees (−135°). The phase difference can be obtained by calculation with the following equation (1).

Phase difference=(time of reference timing 311−time of symbol ▴)/test pattern cycle×360° (1)

Here, the test pattern cycle represents the cycle (time) of the designated frequency. In other words, the test pattern cycle represents the repetition cycle of a test pattern TSP supplied to the semiconductor device 2 during the failure location specifying operation. The reference timing 311 can be desirably set at arbitrary time. Since the delay of a cable or/and a board transmitting the measurement signal DTS from, for example, the laser beam detector 3 to the spectrum analyzer 7 is added as an offset to the measurement result supplied to the computer 5, the reference timing 311 can be desirably set at arbitrary time to cancel the offset. Further, there is a case that the EOFM analyzer itself has a function of adding the offset to the measurement result of the phase map and the offset is adjusted so as to easily see the measurement result. In accordance with this, it is desirable that the reference timing 311 can be arbitrarily set so as to adjust the offset even in the case where the phase map is generated using the circuit simulation.

Here, an example in which the time difference with the reference trigger signal is obtained at the timing at the center of the period during which the logic waveform (operation waveform) becomes the high level has been described, but the present invention is not limited to the example. For example, the time difference maybe obtained at the timing at the center of a period during which the logic waveform becomes the low level. Further, the time difference with the reference trigger signal RFS may be obtained at timing close to the timing at which the logic waveform transits from the low level to the high level (or from the high level to the low level). However, in the case where the time difference with the reference trigger signal RFS is obtained at timing close to the timing at which the voltage of the logic waveform transits, there is a concern that it becomes difficult to obtain an appropriate time difference (phase difference) when, for example, the duty ratio of the logic waveform fluctuates and the transition of the logic waveform temporally shifts back and forth. Therefore, it is desirable to obtain the time difference with the reference trigger signal at the timing at the center of the period during which the logic waveform (operation waveform) becomes the high level (or the low level).

Further, in FIG. 4, the periods before and after the reference timing 311 in terms of time are set as the phase + and the phase −, respectively. However, this may be opposite. Namely, the phase + and the phase − may be determined in accordance with the phase map generated by the EOFM measurement unit 101.

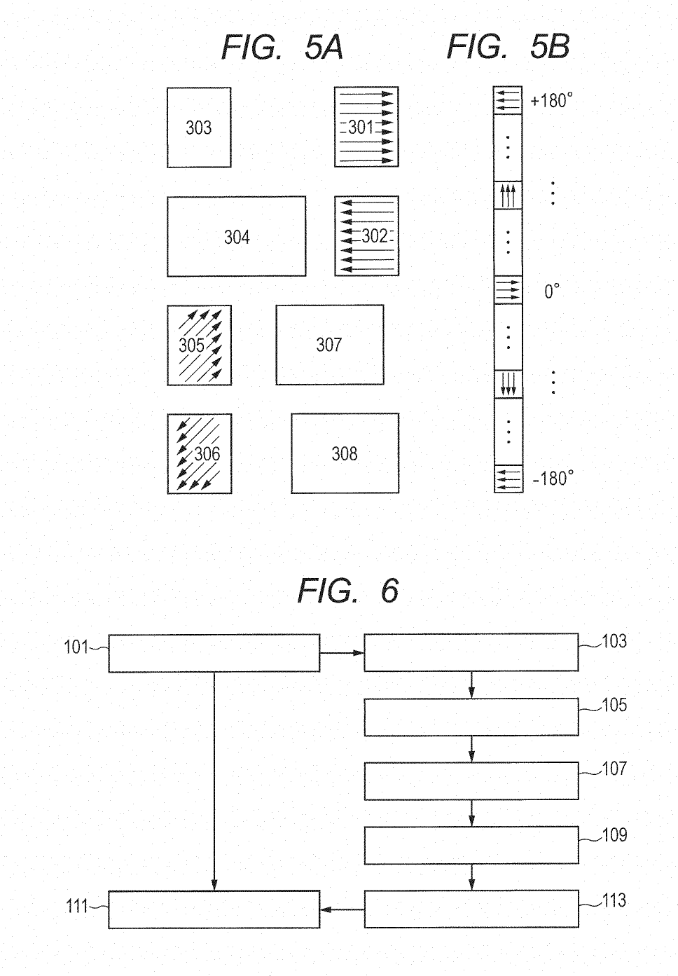

FIGS. 5A and 5B are diagrams each showing a phase map generated by the phase map generation unit 109. Here, FIG. 5A shows the view region of the same semiconductor device 2 as FIG. 3. The phase map generation unit 109 colors the blocks 301 to 308 in the view region with colors corresponding to the phase differences calculated by the phase calculation unit 107. In FIG. 5A, the color is represented by solid lines with arrows. Namely, the in-phase (0°) with the reference trigger signal RFS is represented by solid arrow lines directed laterally rightward, and the direction in which the phase is advanced is represented by rotating the solid arrow lines in the counterclockwise direction with reference to the solid arrow lines of the phase 0°. Therefore, the phase +180° is represented by solid arrow lines directed laterally leftward that are obtained by rotating the solid arrow lines in the counterclockwise direction and by inverting the solid arrow lines directed laterally rightward that represent the phase 0°. Further, the direction in which the phase is delayed is represented by rotating the solid arrow lines in the clockwise direction with reference to the solid arrow lines of the phase 0°. The phase −180° is represented by solid arrow lines directed laterally leftward that are obtained by rotating the solid arrow lines in the clockwise direction and by inverting the solid arrow lines directed laterally rightward that represent the phase 0°.

FIG. 5B is a scale for showing a correspondence between the phase and the solid arrow line (color). In the first embodiment, a color (pure color) is allocated to each of predetermined phases of 360°. On the scale of FIG. 5B, colors (solid arrow lines) corresponding to 0°, +90°, +180°, −90°, and −180° are exemplified.

In FIG. 4, the phase difference of the operation waveform 301 is 0°, and thus the block 301 located at the position where the FET corresponding to the operation waveform 301 is arranged is colored with the color (the solid arrow lines directed laterally rightward) representing the phase 0°. Similarly, the phase difference of the operation waveform 302 is +180°, and thus the block 302 located at the position where the FET corresponding to the operation waveform 302 is arranged is colored with the color (the solid arrow lines directed laterally leftward) representing the phase difference +180°. Similarly, the block 305 is colored with the color (the solid arrow lines directed obliquely in the upper right direction) representing the phase difference +45°, and the block 306 is colored with the color (the solid arrow lines directed obliquely in the lower left direction) representing the phase difference −135°.

On the other hand, the potential difference between the drain region and the source region is not changed in each of the FETs 303, 304, 307, and 308, and thus there is no phase difference with the reference trigger signal. Therefore, the blocks 303, 304, 307, and 308 arranged at the positions corresponding to these FETs are not colored (no solid arrow lines). Since the potential difference between the drain region and the source region is not changed, it can be considered that such FETs are not operated. In such a case, the blocks located at the positions corresponding to the FETs that are arranged in the semiconductor device 2 but not operated are not colored. It is obvious that the regions where no FETs are arranged are not colored. Thus, the phase map generated by the phase map generation unit 109 has only the regions (EOFM reaction regions) colored with the pure colors and the regions without colors.

The phase map comparison unit 111 compares the phase map of the circuit element generated by the EOFM measurement unit 101 with the phase map of the circuit element generated by the phase map generation unit 109. In the comparison, both phase maps are displayed side by side on a display device (not shown), and, for example, a user (operator) visually compares to specify the failure location. Alternatively, the display device may be provided with an overlay display function in which either one of the phase maps is displayed in a translucent or hatched manner, and is overlapped with the other phase map.

According to the first embodiment, the EOFM reaction region in the phase map generated by the EOFM measurement unit 101 can be easily collated with the FET arranged on the semiconductor device 2.

In the phase map generated by the EOFM measurement unit 101, the FETs operated at the same time interval as the cycle of the test pattern are colored in accordance with the phase difference at the positions where the FETs are arranged. On the other hand, a mixed color mixed with a plurality of pure colors is displayed at the positions on the phase map where the FETs that are not operated are arranged and the positions of the regions where no FETs are arranged. Therefore, even if a user views only the phase map generated by the EOFM measurement unit 101, it is difficult to discriminate whether or not the FET is arranged. Further, since the spatial resolution is insufficient, the shape of the EOFM reaction region in the phase map generated by the EOFM measurement unit 101 does not match the arrangement shape of the FET on the layout data RDA. Accordingly, even if the phase map generated by the EOFM measurement unit 101 is simply compared with the layout data RDA, it is difficult to collate each EOFM reaction region with the position of the FET.

On the other hand, according to the first embodiment, in the phase map generated by the phase map generation unit 109, the positions of the operating FETs are colored in accordance with the phase difference, and the positions of the FETs that are not operated and the positions where no FETs are arranged are not colored. Therefore, it is possible to easily discriminate the positions where the operating FETs are arranged by comparing the phase map generated by the EOFM measurement unit 101 with the phase map generated by the phase map generation unit 109.

Further, according to the first embodiment, it is possible to grasp the position of the FET where the EOFM reaction is to occur by referring to the phase map generated by the phase map generation unit 109. Therefore, it is possible to easily collate the EOFM reaction region with the position of the FET by comparing the phase map generated by the EOFM measurement unit 101 with the phase map generated by the phase map generation unit 109.

Furthermore, the circuit simulation unit 105 generates an operation waveform in the case where no failure has occurred in the semiconductor device 2. Therefore, the phase map generation unit 109 generates the phase map when no failure occurs. Thus, by comparison with the phase map generated by the EOFM measurement unit 101 on the basis of the measurement signal from the semiconductor device 2 where a failure occurs, it is possible to specify the failure location where the failure occurs in the semiconductor device 2 from the different part.

In the case where a failure location in the semiconductor device 2 is specified by an optical method such as the EOFM technique, measurement results of non-defective and defective products are usually compared with each other to specify the failure location from the different point. On the other hand, in the first embodiment, the failure location is specified on the basis of the phase map obtained from the defective semiconductor device 2 and the phase map obtained on the basis of the circuit simulation. Therefore, it is possible to eliminate the need for measurement (generation of the phase map by the EOFM measurement unit 101) for the non-defective semiconductor device 2.

### Second Embodiment

FIG. 6 is a block diagram for showing details of a failure location specifying device according to a second embodiment. FIG. 6 is similar to FIG. 2, and thus the differences will be mainly described here. In FIG. 6, a phase map transformation unit 113 is added to FIG. 2. The phase map transformation unit 113 transforms the phase map generated by the phase map generation unit 109. In the second embodiment, the phase map transformation unit 113 transforms the phase map in consideration of the spatial resolution of the EOFM measurement unit 101. In other words, in consideration of the spatial resolution when generating the phase map by the EOFM measurement unit 101, the phase map transformation unit 113 transforms the phase map generated by the phase map generation unit 109. The transformed phase map is supplied to the phase map comparison unit 111 to be compared with the phase map generated by the EOFM measurement unit 101.

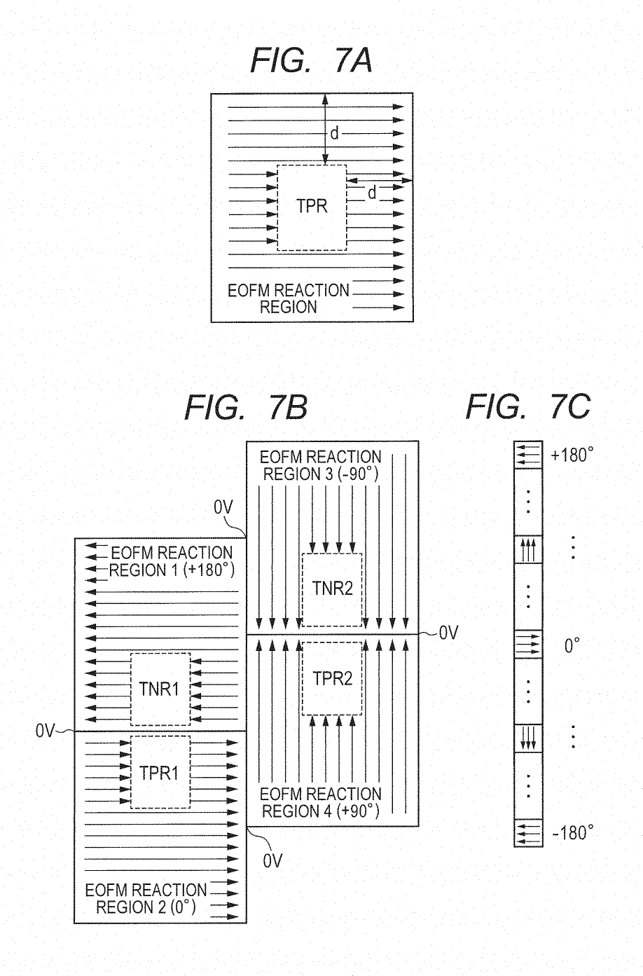

FIGS. 7A and 7B are diagrams each explaining an operation of the phase map transformation unit according to the second embodiment. FIG. 7A is a diagram for schematically showing the phase map generated by the EOFM measurement unit 101. In FIG. 7A, the EOFM reaction region for one P-type FET is shown. A region TPR surrounded by a broken line in FIG. 7A shows a diffusion region (the drain region and the source region) of the P-type FET. It should be noted that the gate electrode is omitted also in FIG. 7A. Since the spatial resolution of the EOFM measurement unit 101 (including the laser beam detector 3 shown in FIG. 1) is insufficient with respect to the size of the FET, the EOFM reaction region appears to be spread in the phase map due to the influence of the diffraction limit. In FIG. 7A, the EOFM reaction region is spread and enlarged by a dimension d with respect to the size of the diffusion region. In the phase map, the enlarged EOFM reaction region is colored in accordance with the phase difference and displayed. In the drawing, the EOFM reaction region is colored with the color (solid arrow lines directed laterally rightward) of the phase difference 0°. It should be noted that in order to easily see the drawing, the solid arrow lines are omitted in the region TPR surrounded by the broken line in FIG. 7A. However, it is obvious that the region TPR is colored with the color of the phase difference 0°. This also applies to FIG. 7B to be described later.

In the second embodiment, the phase map transformation unit 113 transforms the EOFM reaction region in the phase map generated by the phase map generation unit 109 so as to be enlarged only by the dimension d. The phase map generation unit 109 generates the phase map by coloring the diffusion region of the FET as the EOFM reaction region with the color corresponding to the phase difference. For the phase map generated in such a manner, the phase map transformation unit 113 enlarges the EOFM reaction region in the upper, lower, left, and right directions only by the dimension d, and colors the EOFM reaction region obtained by the enlargement with the color corresponding to the phase difference. The process performed by the phase map transformation unit 113 can be regarded as a process in which the spread of the EOFM reaction region due to the influence of the diffraction limit in the EOFM measurement unit 101 including the laser beam detector 3 is simulated.

There are various configurations that set the dimension d. For example, while changing the dimension d, the phase map transformation unit 113 generates the phase map corresponding to each dimension d. The phase map comparison unit 111 compares each of the phase maps thus generated and the phase map generated by the EOFM measurement unit 101 with each other, and the dimension d corresponding to the phase map that matches most with the phase map generated by the EOFM measurement unit is set as the dimension d used in the following phase map transformation unit 113.

Alternatively, the dimension d may be set using the value of the radius r of an Airy disk. Although omitted in FIG. 1, the laser beam detector 3 includes a lens through which the laser beam passes. In general, it is thought that the focus image of a light ray passing through a lens does not strictly become a point but a disk having the size of an Airy disk by diffraction. Since the laser spot diameter when scanning the semiconductor device 2 with a laser beam is also regulated by this, it is conceivable that the value of the spread dimension d of the EOFM reaction region shown in FIG. 7A is close to the radius r of the Airy disk. The radius r of the Airy disk is obtained by the following equation (2).

r=0.61×λ/NA (2)

Here, λ represents the wavelength of light and NA represents the numerical aperture of the optical system. The wavelength λ of the scanning laser beam is, for example, 1300 nm in the EOFM technique.

As described above, by enlarging the EOFM reaction region in the phase map by the phase map transformation unit 113, the matching degree with the EOFM reaction region in the phase map formed by the EOFM measurement unit 101 can be increased, and the visibility can be improved.

On the other hand, in the case where the EOFM reaction region in the phase map is enlarged by the phase map transformation unit 113, it is conceivable that the enlarged EOFM reaction regions are overlapped with each other among the FETs arranged at positions close to each other. In this case, if the phase difference is different between the enlarged EOFM reaction regions, it is conceivable that a region that is not overlapped is colored with a pure color corresponding to the phase difference, but an overlapped region is colored with a mixed color mixed with a plurality of pure colors.

In the second embodiment, in the case where the enlarged EOFM reaction regions are overlapped with each other, the phase map transformation unit 113 forms boundaries in the overlapped regions, and performs a process so as not to mix the pure color. FIG. 7B is a diagram for explaining a process in which the phase map transformation unit 113 forms the boundaries.

FIG. 7B shows the phase map generated by the phase map transformation unit 113 in the case where four FETs are arranged close to each other. In the drawing, TNR1 and TNR2 denote diffusion regions of N-type FETs, and TPR1 and TPR2 denote diffusion regions of P-type FETs. As similar to FIG. 7A, each diffusion region indicates the drain region and the source region, and the gate electrode is omitted.

These FETs are arranged close to each other. Therefore, when the phase map transformation unit 113 enlarges each of the diffusion regions TNR1, TPR1, TPR2, and TNR2 in the upper, lower, left, and right directions only by the dimension d to form the EOFM reaction regions, the EOFM reaction regions are overlapped with each other. Therefore, the phase map transformation unit 113 forms boundaries OV in the regions overlapped each other. When coloring the EOFM reaction regions in accordance with the phase differences, the phase map transformation unit 113 avoids coloring beyond the boundaries OV. Accordingly, only the EOFM reaction region 1 to the EOFM reaction region 4 that are not overlapped with each other as shown in FIG. 7B are colored in accordance with the phase differences. In other words, in the case where the phase regions are overlapped with each other in the phase map, the colored boundaries OV are set in the overlapped regions.

It should be noted that the colored colors are represented by the directions of the solid arrow lines instead of the colors even in FIGS. 7A and 7B. FIG. 7C is a scale for showing the correspondence between the phase and the solid arrow lines as similar to FIG. 5B. The scale discretely divides 360° into 15 pure colors (directions of solid arrow lines). The EOFM reaction region is colored in accordance with the scale. Since the boundary OV is formed between the EOFM reaction regions close to each other and the EOFM reaction regions are not colored beyond the boundary OV, it is possible to prevent the occurrence of an intermediate color. Namely, the boundary OV can be regarded as a boundary between different pure colors.

According to the second embodiment, the phase map generated on the basis of the circuit simulation is more approximate to the phase map generated by the EOFM measurement unit 101 by the transformation by the phase map transformation unit 113. Therefore, each of the EOFM reaction regions in the phase map generated by the EOFM measurement unit 101 and each of the FETs on the layout generated by the circuit simulation can be more easily collated with each other as compared to the first embodiment.

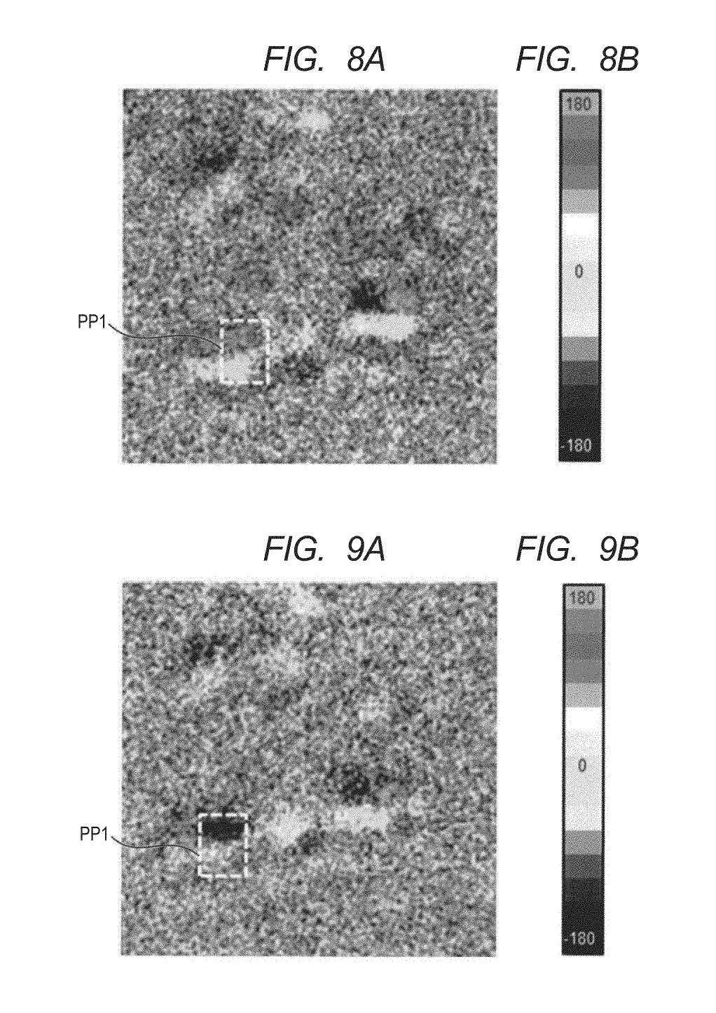

FIG. 8A is a diagram for showing the phase map of the view region of a non-defective semiconductor device generated by the EOFM measurement unit 101. FIG. 9A is a diagram for showing the phase map of the view region of a defective semiconductor device generated by the EOFM measurement unit 101. FIG. 8A and FIG. 9A show the phase maps for the same view regions of the semiconductor devices having the same configuration. It should be noted that FIG. 8B and FIG. 9B are scales each showing a relationship between the color (black gradation) and the phase difference in the phase map shown in each of FIG. 8A and FIG. 9A. Each of the scales is the same as that in FIG. 14B.

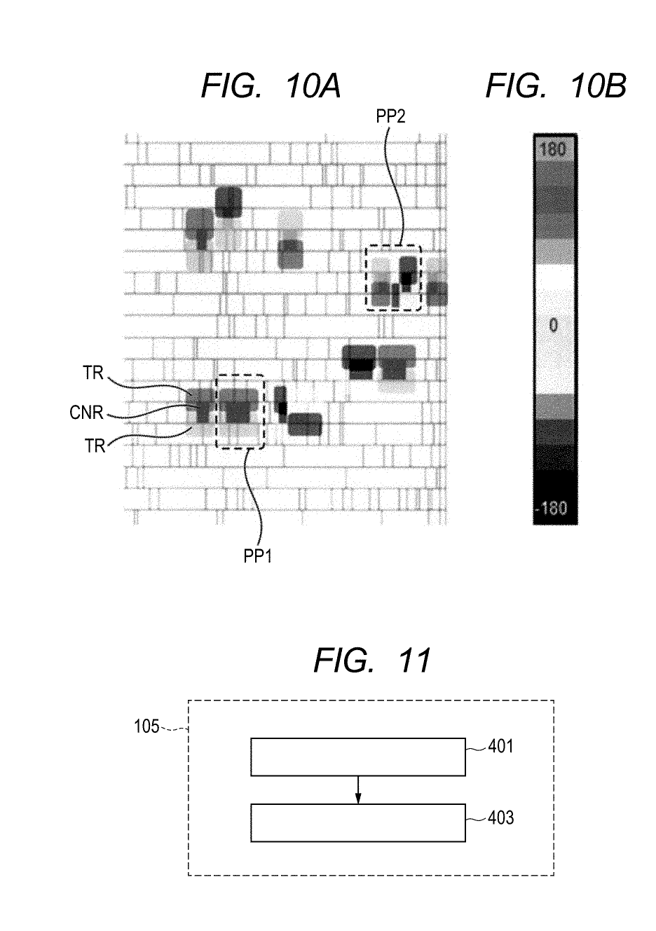

FIG. 10A is a diagram for showing the phase map generated on the basis of the circuit simulation according to the second embodiment. FIG. 10A shows the phase map generated in such a manner that circuit elements in the view regions of the semiconductor devices shown in FIG. 8A and FIG. 9A are extracted and subjected to a circuit simulation according to the second embodiment to generate a phase map and the phase map is transformed by the phase map transformation unit 113. In the transformed phase map shown in FIG. 10A, the diffusion regions (the drain regions and the source regions) of the FETs are shown. In the drawing, TR is attached to each of the diffusion regions of two FETs as an example. The diffusion region of each FET is colored with a color (shade) corresponding to the phase difference. It should be noted that FIG. 10B is a scale as similar to FIG. 8B and FIG. 9B. A region CNR illustrated to connect the diffusion regions TR indicates that a logic cell including the FETs of the connected diffusion regions TR is operated.

In each of FIG. 8A, FIG. 9A, and FIG. 10A, a region PP1 surrounded by a broken line shows the same position in the semiconductor device. With reference to the phase map shown in FIG. 10A, it can be discriminated that two FETs are arranged in the region PP1. With reference to FIG. 8A and FIG. 10A, when comparing the regions PP1 with each other, both have the same shade (color). On the other hand, with reference to FIG. 9A and FIG. 10A, when comparing the regions PP1 with each other, both have different shades (colors). Accordingly, it is possible to specify the occurrence of a failure in the region PP1 in a defective product. As a result, a region where cross-sectional observation needs to be performed can be easily determined.

Further, in FIG. 10A, it can be discriminated that the EOFM reaction regions having six different colors (shades) are present in a region PP2. Since there is no intermediate color at the boundaries among the six EOFM reaction regions, it can be easily discriminated that six FETs are arranged in the region PP2. Namely, the FETs arranged close to each other can be also easily discriminated.

### Third Embodiment

FIG. 11 is a block diagram for showing a configuration of a circuit simulation unit according to a third embodiment. In the embodiment, the configuration of the circuit simulation unit 105 shown in each of the first and second embodiments is changed as shown in FIG. 11. Since the parts other than the circuit simulation unit 105 are similar, the explanation thereof is omitted unless it is necessary.

In the embodiment, the circuit simulation unit 105 is configured using a logic simulation unit 401 and an intra-cell transistor simulation unit 403.

As a configuration of obtaining the operation waveform of an FET, a simulation program called Spice is known. In Spice, on the basis of a net list showing a connection relationship between the FETs, a transistor model showing the performance of each FET, and an input waveform supplied from the outside, the operation waveforms of the respective FETs described on the net list can be obtained. The circuit simulation unit 105 can be configured using, for example, Spice. In this case, for example, the net list and the transistor model are supplied from the storage unit 9 to the circuit simulation unit 105 as the circuit connection data NDA, and the test pattern TPS is supplied as the input waveform.

On the other hand, along with the advanced high integration of the semiconductor device 2, more than one billion FETs can be formed on one semiconductor chip. A circuit simulation for such a large number of FETs with the program such as Spice requires extremely large computer resources, and thus it is practically difficult to realize.

In the third embodiment, as shown in FIG. 11, the circuit simulation unit 105 is configured using the logic simulation unit 401 and the intra-cell transistor simulation unit 403.

The logic simulation unit 401 conducts a waveform simulation using a logic cell configured by the FETs as a unit of a circuit element. In this case, the logic simulation unit 401 excludes the behavior (operation) of the FETs configuring the logic cell from calculation, and calculates only the waveform of the input/output terminal of the logic cell as a target of the simulation. Accordingly, it is possible to reduce the amount of calculation required for the logic simulation unit 401. It should be noted that the logic cell means a circuit including a plurality of FETs and a function of a logic operation such as AND, OR, or the like. As a logic simulation program configuring the logic simulation unit 401, VCS (registered trademark) of Synopsys, Inc., NC-Verilog (registered trademark) of Cadence Design Systems, Inc., and the like are known.

Further, as the intra-cell transistor simulation unit 403, a simulation program such as Spice can be used.

In the third embodiment, the logic simulation unit 401 executes a logic simulation for all the logic cells arranged in the semiconductor device 2. At this time, the logic simulation unit 401 also calculates the waveform at the input/output terminal of the logic cell arranged in the observation region. At this point, the operation waveforms of the FETs configuring the logic cell are unknown. Next, the intra-cell transistor simulation unit 403 calculates the operation waveforms of the FETs configuring the logic cell on the basis of the waveform at the input/output terminal of the logic cell. From a different viewpoint, the logic simulation unit 401 calculates the waveforms of all the logic cells arranged in the semiconductor device 2, and the waveform calculated only for the logic cell arranged in the observation region is supplied to the intra-cell transistor simulation unit 403. Then, the intra-cell transistor simulation unit 403 calculates the operation waveform of the FET arranged in the observation region.

Namely, the simulation of a large-scale circuit is performed by the logic simulation unit 401 the speed of which can be increased by reducing the amount of calculation, and the simulation of the intra-cell transistor that requires time to calculate is performed by limiting to the FETs arranged in the observation field of view at the time of the failure location specifying operation. Accordingly, the number of FETs that are subjected to the simulation requiring time to calculate can be reduced, and the necessary computer resources can be reduced.

In this case, for example, cell position data indicating the position of the logic cell in the semiconductor device 2, correspondence data indicating a correspondence relationship between the position of the logic cell and the logic cell in the circuit connection data, and FET position data indicating the positions of the FETs configuring the logic cell are stored in the storage unit 8 (FIG. 1), and are supplied to the computer 5 as the layout data RDA.

For example, the EOFM measurement unit 101 shown in FIG. 2 obtains the coordinate range information of the logic cell from the coordinate range of the specified observation target, and supplies the obtained coordinate range information of the logic cell to the circuit extraction unit 103. The circuit extraction unit 103 specifies and extracts the logic cell included in the specified coordinate range from the supplied coordinate range information of the logic cell. In the extraction, the circuit extraction unit 103 uses the cell position data in the layout data RDA supplied from the storage unit 8. The logic cell in the circuit connection data NDA corresponding to the specified logic cell is specified using the corresponding data included in the layout data RDA.

The intra-cell transistor simulation unit 403 calculates the operation waveforms of the FETs in the logic cell by using the waveform and the like at the input/output terminal of the logic cell obtained by the operation by the logic simulation unit 401. Thereafter, although not particularly limited, the positions of the FETs configuring the logic cell are specified using the FET position data in the layout data RDA, and are colored in accordance with the phase differences.

According to the third embodiment, the number of FETs that are subjected to the simulation requiring time to calculate can be reduced, and the necessary computer resources can be reduced.

### Modified Example

In this modified example, the operation waveforms of the FETs configuring the logic cell are set on the basis of the waveform at the input/output terminal of the logic cell.

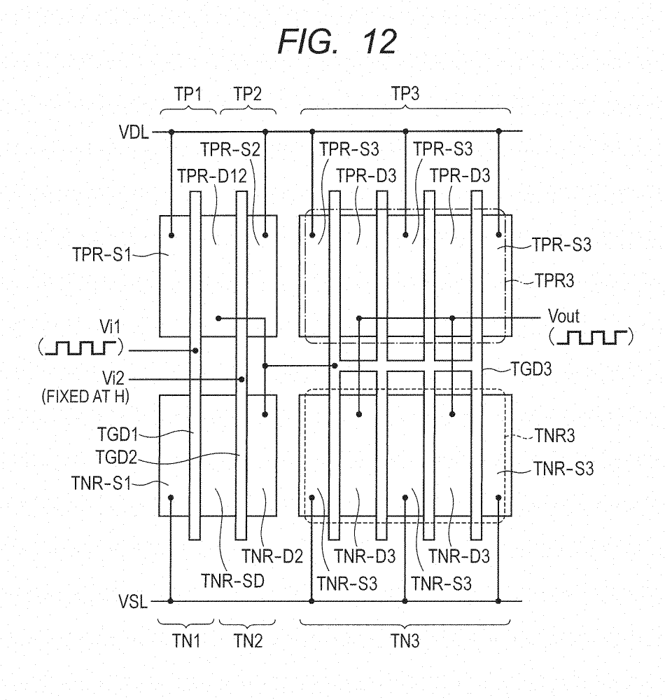

FIG. 12 is a plan view for explaining a failure location specifying device according to the modified example of the third embodiment. In the drawing, a schematic plane of the logic cell formed in the semiconductor device 2 is shown. Here, a two-input AND circuit will be described as an example of the logic cell. However, the configuration of the logic cell is not limited to this. The 2-input AND circuit includes P-type FETs TP1 to TP3 and N-type FETs TN1 to TN3. The source regions TPR-S1 and TPR-S2 of the P-type FETs TP1 and TP2 are coupled to a power source line VDL to which a power source voltage Vd is supplied, and the respective drain regions of the P-type FETs TP1 and T2 serve as a common drain region TPR-D12. Further, the source region TNR-S1 of the N-type FET TN1 is coupled to a ground line VSL to which a ground voltage Vs is supplied, and the drain region of the N-type FET TN1 and the source region of the N-type FET TN2 serve as a common semiconductor region TNR-SD. The drain region TNR-D2 of the N-type FET TN2 is coupled to the common drain region TPR-D12 of the P-type FETs TP1 and TP2. The respective gate electrodes of the P-type FET TP1 and the N-type FET TN1 serve as a common gate electrode TGD1 for these FETs. Likewise, the gate electrodes of the P-type FET TP2 and the N-type FET TN2 also serve as a common gate electrode TGD2 for these FETs.

The P-type FET TP3 and the N-type FET TN3 include a common gate electrode TGD3, and the gate electrode TGD3 is coupled to the drain regions of the P-type FETs TP1 and TP2 and the N-type FETs TN1 and TN3. The gate electrode TGD3 has a comb shape toward the regions of the P-type FET TP3 and the N-type FET TN3. The P-type FET TP3 includes source regions TPR-S3 and drain regions TPR-D3 arranged so as to alternately sandwich protruding portions of the comb shape. Likewise, the N-type FET TN3 also includes source regions TNR-S3 and drain regions TNR-D3 arranged so as to alternately sandwich protruding portions of the comb shape. The source region TPR-S3 of the P-type FET TP3 is coupled to the power source line VDL, and the source region TNR-S3 of the N-type FET TN3 is coupled to the ground line VSL. Further, the respective drain regions TPR-D3 and TNR-D3 of the P-type FET TP3 and the N-type FET TN3 are commonly coupled.

The common gate electrode TGD1 of the P-type FET TP1 and the N-type FET TN1 serves as a first input terminal of the logic cell, and the common gate electrode TGD2 of the P-type FET TP2 and the N-type FET TN2 serves as a second input terminal of the logic cell. Further, the drain regions of the P-type FET TP3 and the N-type FET TN3 that are commonly coupled serve as output terminals of the logic cell. When a first input signal Vi1 is supplied to the first input terminal and a second input signal Vi2 is supplied to the second input terminal, the AND logic is formed by the P-type FETs TP1 and TP2 and the N-type FETs TN1 and TN2. The voltage of the formed logic signal is output from the output terminal as an output signal Vout by an inverter circuit configured using the P-type FET TP3 and the N-type FET TN3. The P-type FET TP3 and the N-type FET TN3 function as a buffer circuit, and thus are illustrated larger in size than the P-type FETs TP1 and TP2 and the N-type FETs TN1 and TN2.

In the case where the second input signal Vi2 supplied to the logic cell is fixed at, for example, a high level (H), the output signal Vout from the logic cell has a waveform that changes in synchronization with the voltage change of the first input signal Vi1.

In the EOFM technique, reflected light changes due to a strong influence by the potential difference between the drain region and the source region of the FET. When viewing a diffusion region TNR3 in FIG. 12, the drain region TNR-D3 of the N-type FET TN3 serves as the output terminal of the logic cell, and the source region TNR-S3 of the N-type FET TN3 is coupled to the ground line VSL. Therefore, when paying attention to the N-type FET TN3, a change in the potential difference between the drain region TNR-D3 and the source region TNR-S3 becomes the same (the same phase) as the waveform at the output terminal of the logic cell. On the other hand, when viewing a diffusion region TPR3 in FIG. 12, the drain region TPR-D3 of the P-type FET TP3 serves as the output terminal of the logic cell, and the source region thereof is coupled to the power source line VDL. Therefore, when paying attention to the P-type FET TP3, a change in the potential difference between the drain region TPR-D3 and the source region TPR-S3 corresponds to a change (opposite phase) in which the waveform at the output terminal of the logic cell is inverted.

As described above, in the FET including the semiconductor region (drain region) serving as the output terminal of the logic cell or the semiconductor region coupled to the output terminal of the logic cell among those configuring the logic cell, a change in the potential difference between the drain region and the source region becomes the in-phase or anti-phase of the waveform at the output terminal of the logic cell. By utilizing this in the modified example, the waveform at the output terminal of the logic cell calculated by the logic simulation unit 401 and the waveform of the inverted phase are supplied to the phase calculation unit 107 as the operation waveform (logic waveform) of the circuit element described in the first embodiment, and the phase difference with the reference trigger signal is calculated. Accordingly, it is not necessary to provide the intra-cell transistor simulation unit 403, and it is possible to further shorten the time required to specify the failure location.

In the modified example, the potential difference between the drain region and the source region cannot be obtained for the FET that is not coupled to the output terminal of the logic cell, and thus the operation of the FET is strictly different from the actual operation of the logic cell. Namely, the phase map including all the FETs configuring the logic cell cannot be generated. However, since the size of the FET coupled to the output terminal tends to be the largest in the logic cell, even if it is assumed that the EOFM reaction does not occur in the FET that is not coupled to the output terminal, the phase map approximate to the phase map generated by the EOFM measurement unit 101 can be generated on the basis of the waveform obtained by the logic simulation unit 401.

According to the third embodiment, it is possible to reduce the operation time in the circuit simulation unit used to generate the phase map. Therefore, in the case of a large-scale semiconductor device in particular, the necessary computer resources become huge, and there is a possibility that the calculation becomes virtually impossible. However, the computer resources can be reduced to the range of computer resources that can be actually realized.

The EOFM measurement unit 101, the circuit extraction unit 103, the circuit simulation unit 105, the phase calculation unit 107, the phase map generation unit 109, and the phase map transformation unit 113 may be realized by one computer 5, but may be dispersedly realized by a plurality of computers. For example, each of the above-described units may be realized by a separate computer. Alternatively, these units are divided into a plurality of sections, and each of the divided sections may be realized by a separate computer.

Further, the first to third embodiments have been described from the viewpoint of the failure location specifying device. However, each unit can be regarded as a method. Namely, the EOFM measurement unit 101 may be regarded as an EOFM measurement process, the circuit extraction unit 103 maybe regarded as a circuit extraction process, the circuit simulation unit 105 may be regarded as a circuit simulation process, the phase calculation unit 107 may be regarded as a phase calculation process, the phase map generation unit 109 may be regarded as a phase map generation process, and the phase map transformation unit 113 may be regarded as a phase map transformation process. Further, the phase map comparison unit 111 may be also regarded as a phase map comparison process, the logic simulation unit 401 may be regarded as a logic simulation process, and the intra-cell transistor simulation unit 403 may be regarded as an intra-cell transistor simulation process. In such a case, the first to third embodiments should be understood as disclosing a failure location specifying method.

The semiconductor device 2 includes, for example, a logic circuit configured using a plurality of logic cells and a plurality of flip-flop circuits configuring a scan chain that is coupled in series so as to supply a test pattern to the logic circuit when conducting a test. According to the technique disclosed in “Realization of random logic operation analysis by short-cycle test pattern, The 35th Nano Testing Symposium Proceedings, P. 203 to P. 208, Nov. 11, 2015”, in the failure location specifying operation, the test pattern generator 6 can generate a test pattern TPS that is shorter than the length of the scan chain and that can cause the potential to perform a transition operation at a predetermined position (net) in the logic circuit, and can repeatedly supply the test pattern TPS to the semiconductor device 2 in a predetermined loop cycle. In the first to third embodiments, the test pattern TPS is made shorter than the length of the scan chain, and is supplied to the semiconductor device 2 as a short-cycle test pattern. Since the test pattern TPS becomes shorter, the repeated loop cycle of the test pattern TPS can be shortened, and it is possible to reduce the occurrence of a signal of a frequency other than the frequency component corresponding to the loop cycle. Further, it is also possible to shorten the time required for one test. The designated frequency is made substantially the same as, for example, the frequency of the above-described loop cycle. Accordingly, it is possible to reduce frequency components other than the designated frequency included in the measurement signal.

It should be noted that the computer 5 shown in FIG. 1 controls the laser beam detector 3, the stage 4, the test pattern generator 6, the spectrum analyzer 7, and the like when performing the operation of the EOFM measurement unit 101. Therefore, the EOFM measurement unit 101 can be regarded as including these configurations to be controlled.

The invention achieved by the inventors has been concretely described above on the basis of the embodiments. However, it is obvious that the present invention is not limited to the above-described embodiments, and can be variously changed without departing from the gist thereof. For example, it is obvious that the first to third embodiments may be combined with each other.

What is claimed is:

1. A failure location specifying device comprising:
a measurement unit that calculates a phase difference between a measurement signal on the basis of reflected light in accordance with the operation of a circuit element arranged in a semiconductor device and a reference signal, and generates a phase map of the circuit element in the semiconductor device;
a circuit extraction unit that extracts the circuit element included in the field of view in the semiconductor device;
a simulation unit that calculates the operation waveform of the circuit element extracted by the circuit extraction unit by a simulation;
a phase calculation unit that calculates a phase from the operation waveform calculated by the simulation unit; and
a phase map generation unit that generates a phase map of the extracted circuit element on the basis of the phase calculated by the phase calculation unit,
wherein a failure location is specified by using the phase map generated by the measurement unit and the phase map generated by the phase map generation unit.

2. The failure location specifying device according to claim 1, comprising a phase map transformation unit that transforms the phase map generated by the phase map generation unit in accordance with the spatial resolution of the measurement unit.

3. The failure location specifying device according to claim 2,
wherein when phase regions are overlapped with each other in the phase map transformed by the phase map transformation unit, a boundary is generated at the overlapped location.

4. The failure location specifying device according to claim 1,
wherein the simulation unit includes a logic simulation unit that conducts a logic simulation of a logic circuit configured using a plurality of circuit elements and a circuit simulation unit that conducts a simulation of the circuit elements.

5. The failure location specifying device according to claim 1,
wherein the simulation unit includes a logic simulation unit that conducts a logic simulation of a logic circuit configured using a plurality of circuit elements, and
wherein the phase calculation unit calculates a phase from the operation waveform at an output terminal of the logic circuit calculated by the logic simulation.

6. The failure location specifying device according to claim 1,
wherein the circuit element includes a transistor having a gate electrode, a source region, and a drain region.

7. The failure location specifying device according to claim 6,
wherein the measurement unit and the phase map generation unit generate the phase map having colors in accordance with the phases.

8. The failure location specifying device according to claim 3,
wherein the circuit element includes a transistor having a gate electrode, a source region, and a drain region, and
wherein the phase map transformed by the phase map transformation unit is a phase map colored in accordance with the phases, and the boundary is a colored boundary.

9. A failure location specifying method comprising:
a measurement step of irradiating a laser beam to a semiconductor device, calculating a phase difference between a measurement signal on the basis of reflected light in accordance with the operation of a circuit element arranged in the semiconductor device and a reference signal, and generating a phase map of the circuit element in the semiconductor device;
a circuit element extraction step of extracting the circuit element included in the field of view in the semiconductor device;
a simulation step of calculating the operation waveform of the circuit element extracted in the circuit element extraction step by a simulation;
a phase calculation step of calculating a phase from the operation waveform calculated in the simulation step;
a phase map generation step of generating a phase map of the extracted circuit element on the basis of the phase calculated in the phase calculation step, and
a phase map comparison step of comparing the phase map generated in the measurement step with the phase map generated in the phase map generation step.

10. The failure location specifying method according to claim 9, comprising a phase map transformation step of transforming the phase map generated in the phase map generation step on the basis of the spatial resolution when generating the phase map in the measurement step.

11. The failure location specifying method according to claim 10,
wherein in the case where phase regions are overlapped with each other in the phase map when transforming the phase map, a boundary is set at the overlapped region in the phase map transformation step.

12. The failure location specifying method according to claim 9,
wherein the simulation step includes a logic simulation step of conducting a logic simulation of the entire semiconductor device and a circuit simulation step of calculating the operation waveform of the circuit element included in the field of view.

13. The failure location specifying method according to claim 12,
wherein in the phase calculation step, a phase is calculated on the basis of the waveform at an output terminal of the logic circuit calculated in the logic simulation step.

14. The failure location specifying method according to claim 9,
wherein the phase map colored in accordance with the phases is generated in the measurement step and the phase map generation step.

15. The failure location specifying method according to claim 11,
wherein the circuit element includes a transistor having a gate electrode, a source region, and a drain region, and
wherein the phase map transformed in the phase map transformation step is a phase map colored in accordance with the phases, and the boundary is a colored boundary.
